(19) United States
(12) Patent Application Publication
(10) Pub. No.: US 2023/0245915 A1
(43) Pub. Date: Aug. 3, 2023

(54) WAFER TRANSFER DEVICE, WAFER TRANSFER METHOD AND CLEANING MODULE OF CHEMICAL MECHANICAL PLANARIZATION MACHINE

(71) Applicant: HANGZHOU SIZONE ELECTRONIC TECHNOLOGY INC., Zhejiang (CN)

(72) Inventors: Yuansi YANG, Zhejiang (CN); Linghan SHEN, Zhejiang (CN); Zhipeng ZHOU, Zhejiang (CN)

(73) Assignee: HANGZHOU SIZONE ELECTRONIC TECHNOLOGY INC., Zhejiang (CN)

(21) Appl. No.: 17/908,239

(22) PCT Filed: Oct. 12, 2020
(86) PCT No.: PCT/CN2020/120376

§ 371 Date: Aug. 31, 2022

(30) Foreign Application Priority Data
May 6, 2020 (CN) 202010373153.6

(51) Int. Cl. H01L 21/687; H01L 21/67; H01L 21/677

(52) U.S. Cl. CPC H01L 21/68721; H01L 21/67028; H01L 21/67706

(57) ABSTRACT

A wafer transfer device, a wafer transfer method and a cleaning module of a chemical mechanical planarization machine are provided. The wafer transfer device comprises: at least one claw clamping arm module for picking up and placing a wafer; at least one Z-axis moving module, connected to the claw clamping arm module, for performing a movement of the claw clamping arm module in a Z-axis direction; and at least one X-axis moving module, connected to a lower end of the Z-axis moving module, for performing a movement of the claw clamping arm module in a X-axis direction.

### TECHNICAL FIELD

The present disclosure relates to a field of semiconductor integrated circuit chip manufacturing equipment, more specifically, to a wafer transfer device, a transfer method and a cleaning module of a chemical mechanical planarization (CMP) machine.

### DESCRIPTION OF RELATED ART

The chemical mechanical planarization (CMP) machine usually includes a semiconductor equipment front end system (EFEM), a cleaning system and a polishing system. A wafer is transferred by a manipulator among different systems. There are several wafer cleaning units in the cleaning system, and the wafer is cleaned in each unit in turn; during such process, a wafer transfer device is required to complete the task of transferring the wafer. A claw clamping arm of the wafer transfer device puts the wafer to be cleaned into the cleaning module and takes out the cleaned wafer from the unit, and the entire wafer transfer device needs to be kept highly clean. In existing devices, the wafer transfer device is installed by hanging. However, during use, impurities or particles on the device suffering from wear or friction of the device may fall into the cleaning modules, which affect the wafer cleaning effect. Therefore, the wafer transfer device of the existing cleaning system need to be improved, so that the entire device can complete the function while minimizing the number and possibility of particles falling from the device.

### SUMMARY

The present disclosure provides a wafer transfer device, a transfer method and a cleaning module of a chemical mechanical planarization (CMP) machine. A X-transfer axis of the wafer transfer device of the cleaning module of the CMP machine is installed at a lower end of Z-transfer axis. It satisfies a wafer transfer among each of cleaning modules of the CMP machine while it effectively reduces impurities and particles falling down and improves a wafer cleaning effect.

In order to achieve above purpose, the present disclosure provides a wafer transfer device for a cleaning module of a CMP machine, the cleaning module of the CMP machine at least comprises an anterior cleaning channel module, a cleaning module and a drying module, the wafer transfer device comprises:
at least one claw clamping arm module for picking up and placing a wafer;
at least one Z-axis moving module, connected to the claw clamping arm module, for performing a movement of the claw clamping arm module in a Z-axis direction;
at least one X-axis moving module, connected to a lower end of the Z-axis moving module, for performing a movement of the claw clamping arm module in an X-axis direction.

Further, the X-axis moving module comprises: a X-transfer axis; an X-axis driver; and at least one X-axis moving slider, wherein the X-axis driver drives the X-axis moving slider installed on the X-transfer axis to move in the X-axis direction along the X-transfer axis, and the X-axis moving slider is connected to at least one Z-axis moving module.

Further, the Z-axis moving module comprises: a Z-transfer axis; a Z-axis driver; and a Z-axis moving slider, wherein the Z-axis driver drives the Z-axis moving slider installed on the Z-transfer axis to move in the Z-axis direction along the Z-transfer axis, and the Z-axis moving slider is connected to at least one claw clamping arm module.

Further, the claw clamping arm module comprises a claw clamping arm, the claw clamping arm takes the Z-axis moving slider as an original point and rotates 360° on a plane formed by the X-axis and the Z-axis.

The present disclosure also provides a cleaning module of a CMP machine, comprising: at least one anterior cleaning channel module, at least one cleaning module, and at least one drying module and the wafer transfer device.

The present disclosure also provides a wafer transfer method of using the wafer transfer device:
the X-axis moving module drives the Z-axis moving module and the claw clamping arm module to move in the X-axis direction, and performs the movement of the wafer between any two of the anterior cleaning channel module, the cleaning module and the drying module;
the Z-axis moving module drives the claw clamping arm module to move in the Z-axis direction, and performs the movement of the wafer at any one of the anterior cleaning channel module, the cleaning module and the drying module in the Z-axis direction;
the claw clamping arm module performs picking up and placing the wafer at any one of the anterior cleaning channel module, the cleaning module and the drying module.

Further, the X-axis driver drives at least one X-axis moving slider installed on the X-transfer axis to move in the X-axis direction along the X-transfer axis, and the X-axis moving slider drives at least one Z-axis moving slider to move in the X-axis direction along the X-transfer axis.

Further, the Z-axis driver drives at least one Z-axis moving slider installed on the Z-transfer axis to move in the Z-axis direction along the Z-transfer axis, and the Z-axis moving slider drives the claw clamping arm module to move in the Z-axis direction along the Z-transfer axis.

Further, the claw clamping arm takes the Z-axis moving slider as the original point and rotates 360° on the plane formed by the X-axis and the Z-axis.

The present disclosure has following advantages:
1. The X-transfer axis of the wafer transfer device is installed at the lower end of the Z-transfer axis. It reduces the possibility of impurities and particles of the wafer transfer device falling on the wafer, and improves the wafer cleaning effect;
2. The X- transfer axis of the wafer transfer device is installed at the lower end of the Z-transfer axis. It shortens the moving distance of the wafer transfer device in the Z-axis direction, indirectly shortens the length of the Z-transfer axis, and saves space of the cleaning area.
3. The X-transfer axis of the wafer transfer device is installed at the lower end of the Z-transfer axis. A distance between the claw clamping arm and the Z-transfer axis moving slider is closer, and a stability of the claw clamping arm during picking up and placing the wafer is higher.
4. The X-transfer axis of the wafer transfer device is installed at the lower end of the Z-transfer axis. It lowers the overall center of gravity of the wafer transfer device, moves at a height closer to the cleaning module in the process of transporting wafer, which the way of movement can shorten the time of transporting wafer, and reduces a tremble of the claw clamping arm in the process of transporting wafer .
5. The number of the X-transfer axis of the wafer transfer device is at least one. When the number of the X-transfer axis are increased, the time of transferring wafer among the cleaning modules can be shortened; manipulators can be individually arranged for the cleaning modules with high cleanliness requirements to satisfy higher cleanliness requirements, and the wafer can be transferred among the cleaning modules placed at different locations.
6. The number of the Z-transfer axis installed on the X-transfer axis moving slider of the wafer transfer device is at least one. When the number of the Z-transfer axis are increased, the wafer transfer can have some flexible configuration, and the overall transfer time can be shortened.

### BRIEF DESCRIPTION OF THE DRAWINGS

FIG. 1 is a structural view of a first embodiment of a cleaning module of a CMP machine provided by the present disclosure.

FIG. 2 is a structural view of a second embodiment of a cleaning module of a CMP machine provided by the present disclosure.

FIG. 3 is a structural view of a third embodiment of a cleaning module of a CMP machine provided by the present disclosure.

FIG. 4 is a structural view of a fourth embodiment of a cleaning module of a CMP machine provided by the present disclosure.

FIG. 5 is a structural view of a fifth embodiment of a cleaning module of a CMP machine provided by the present disclosure.

FIG. 6 is a structural view of a sixth embodiment of a cleaning module of a CMP machine provided by the present disclosure.

### DESCRIPTION OF THE EMBODIMENTS

A wafer transfer device of a cleaning module of a chemical mechanical planarization (CMP) machine provided by the present disclosure is further described in detail below by combining the attached drawings and specific embodiments. According to description and the scope of claims, the advantages and features of the present disclosure are clearer. It should be noted that, the attached drawings adopt in simplified forms and imprecise scale, and they are only used to conveniently and clearly illustrate purposes of the embodiments of the present disclosure.

The present disclosure provides a wafer transfer device, which is used for a cleaning module of a CMP machine, the cleaning module of the CMP machine at least includes an anterior cleaning channel module, a cleaning module and a drying module. The wafer transfer device includes: at least one claw clamping arm, which is used for picking up and placing the wafer; at least one Z-axis moving module, which is connected to the claw clamping arm, which is used for performing a movement of the claw clamping arm in a Z-axis direction; at least one X-axis moving module, which is connected to a lower end of the Z-axis moving module, which is used for performing a movement of the claw clamping arm in an X-axis direction.

The X-axis moving module includes a X-transfer axis, an X-axis driver and at least one X-axis moving slider; the X-transfer axis is deposited on a side of the cleaning module of the CMP machine; the X-axis moving slider is fixedly installed on the X-transfer axis; the X-axis driver is deposited on an end of driving the X-transfer axis, which is used for driving the X-axis moving slider to move in the X-axis direction along the X-transfer axis.

The Z-axis moving module includes a Z-transfer axis, a Z-axis driver and at least one Z-axis moving slider; the Z-axis moving slider is fixedly installed on the Z-transfer axis; an end of the Z-axis driver is fixed on the X-axis moving slider, the other end is connected to the Z-transfer axis, which is used for driving the Z-axis moving slider to move in the Z-axis direction along the Z-transfer axis.

The claw clamping arm module is installed on the Z-axis moving slider, the claw clamping arm module includes a claw clamping arm, the claw clamping arm takes the Z-axis moving slider as an original point and rotates 360° on the plane formed by the X-axis and the Z-axis.

The installation manner of a plurality of the X-axis moving modules includes but not limited to overlapping installation along the Y-axis or parallel installation along the X-axis.

A wafer transfer method, includes:
the X-axis moving module drives the Z-axis moving module and the claw clamping arm module to move in the X-axis direction, and performs the movement of the wafer between any two of the anterior cleaning channel module, the cleaning module and the drying module;
the Z-axis moving module drives the claw clamping arm module to move in the Z-axis direction, and performs the movement of the wafer at any one of the anterior cleaning channel module, the cleaning module and the drying module in the Z-axis direction;
the claw clamping arm module performs picking up and placing the wafer at any one of the anterior cleaning channel module, the cleaning module and the drying module.

Under a coaction of the X-axis moving module and the Z-axis moving module, the movement of the claw clamping arm module on the plane formed by the X-axis and the Z-axis is eventually performed. The X-axis moving module, the Z-axis moving module and the claw clamping arm module have the coaction to perform transferring, picking up and placing the wafer among each of modules of the cleaning module of the CMP machine, and then finish the cleaning of the wafer.

The present disclosure also provides a cleaning module of a CMP machine, including: at least one anterior cleaning channel module, at least one cleaning module, at least one drying module and the wafer transfer device; the anterior cleaning channel module is used for storing the wafer to be cleaned; the cleaning module is used for cleaning the wafer; the drying module is used for drying the cleaned wafer. The placement order of the anterior cleaning channel module, the cleaning module and the drying module can be arranged in sequence on the side of the wafer transfer device or be arranged in disorder on the side of the wafer transfer device.

For clarity, the cleaning module in the embodiments of the present disclosure includes an anterior cleaning channel module, a first cleaning module, a second cleaning module, a drying module, the anterior cleaning channel module, the first cleaning module, the second cleaning module and the drying module, which are arranged in sequence along the X-transfer axis direction, and each module has a wafer.

### Embodiment 1

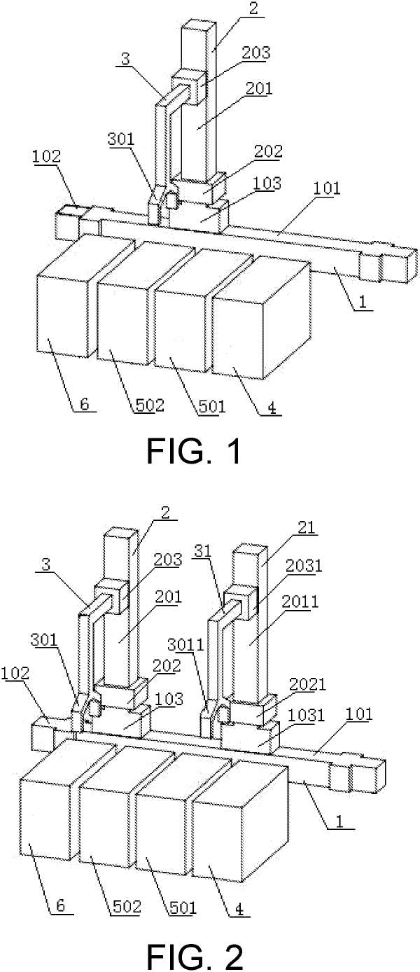

As shown in FIG. 1, it is the first embodiment of the cleaning module of the CMP machine provided in the present disclosure, the wafer transfer device of the cleaning module of the CMP machine includes one X-axis moving module 1, one Z-axis moving module 2 and one claw clamping arm module 3. The X-axis moving module 1 is deposited on a side of the cleaning module of the CMP machine, the X-axis moving module includes a X-transfer axis 101, an X-axis driver 102 and one X-axis moving slider 103. The Z-axis moving module 2 is fixedly installed on the X-axis moving slider 103, the Z-axis moving module 2 includes a Z-transfer axis 201, a Z-axis driver 202 and a Z-axis moving slider 203. The claw clamping arm module 3 is installed on the Z-axis moving slider 203, the claw clamping arm module 3 includes a claw clamping arm 301, which can rotate around the Z-axis moving slider 203.

In this embodiment, the wafer transfer method of the wafer transfer device is:

The X-axis driver 102 moves and drives the Z-axis moving module 2 fixed on the X-axis moving slider 103 to move, the Z-axis moving module 2 moves above the drying module 6, the Z-axis driver 202 drives the claw clamping arm module 3 installed on the Z-axis moving slider 203 to move upward and downward, the claw clamping arm 301 takes out the dried wafer from the drying module 6 and places the wafer into the following process of the CMP machine. Then, the Z-axis moving module 2 moves above the second cleaning module 502, the claw clamping arm 301 takes out the wafer from the second cleaning module 502. The Z-axis moving module 2 further moves above the drying module 6, the claw clamping arm 301 places the wafer taken from the second cleaning module 502 into the drying module 6. After that, the Z-axis moving module 2 further moves above the first cleaning module 501, the claw clamping arm 301 takes out the wafer from the first cleaning module 501. The Z-axis moving module 2 further moves above the second cleaning module 502, the claw clamping arm 301 places the wafer taken from the first cleaning module 501 into the second cleaning module 502. The Z-axis moving module 2 further moves above the anterior cleaning channel module 4, the claw clamping arm 301 takes out one wafer to be cleaned from the anterior cleaning channel module 4. The Z-axis moving module 2 further moves above the first cleaning module 501, the claw clamping arm 301 places the wafer taken from the anterior cleaning channel module 4 into the first cleaning module 501. Afterwards, the Z-axis moving module 2 moves above the drying module 6. Above operations are repeated.

### Embodiment 2

As shown in FIG. 2, it is the second embodiment of the cleaning module of the CMP machine provided in the present disclosure, compared with the first embodiment, the second embodiment further includes one first Z-axis moving module 21 and one first claw clamping arm module 31. The wafer transfer device of the cleaning module of the CMP machine provided in this embodiment includes the X-axis moving module 1, the Z-axis moving module 2, the first Z-axis moving module 21, the claw clamping arm module 3 and the first claw clamping arm module 31. The X-axis moving module 1 is deposited on a side of the cleaning module of the CMP machine, the X-axis moving module 1 includes a X-transfer axis 101, an X-axis driver 102, an X-axis moving slider 103 and a first X-axis moving slider 1031, the X-axis moving slider 103 and the first X-axis moving slider 1031 independently move on the X-transfer axis 101. The Z-axis moving module 2 is fixedly installed on the X-axis moving slider 103, the Z-axis moving module 2 includes a Z-transfer axis 201, a Z-axis driver 202 and a Z-axis moving slider 203. The first Z-axis moving module 21 is fixedly installed on the first X-axis moving slider 1031, the first Z-axis moving module 21 includes a first Z-transfer axis 2011, a first Z-axis driver 2021 and a first Z-axis moving slider 2031. The Z-axis moving module 2 and the first Z-axis moving module 21 independently move on the X-axis moving module 1. The claw clamping arm module 3 is installed on the Z-axis moving slider 203, the claw clamping arm module 3 includes a claw clamping arm 301, which can rotate around the Z-axis moving slider 203. The first claw clamping arm module 31 is installed on the first Z-axis moving slider 2031, the first claw clamping arm module 31 includes a first claw clamping arm 3011, which can rotate around the first Z-axis moving slider 2031.

In this embodiment, the wafer transfer method of the wafer transfer device of the cleaning module of the CMP machine is:

The X-axis driver 102 moves and drives the Z-axis moving module 2 to move above the anterior cleaning channel module 4, the claw clamping arm 301 takes out one wafer to be cleaned from the anterior cleaning channel module 4. Then, the Z-axis moving module 2 and the first Z-axis moving module 21 move together. After the first Z-axis moving module 21 moves above the first cleaning module 501 and the first claw clamping arm 3011 takes out the wafer from the first cleaning module 501, the Z-axis moving module 2 further moves above the first cleaning module 501 and places the wafer taken from the anterior cleaning channel module 4 into the first cleaning module 501. Next, the Z-axis moving module 2 and the first Z-axis moving module 21 move together above the second cleaning module 502, the claw clamping arm 301 takes out the wafer from the second cleaning module 502, the first claw clamping arm 3011 places the wafer taken from the first cleaning module 501 into the second cleaning module 502. After that, the Z-axis moving module 2 further moves above the drying module 6, the claw clamping arm 301 places the wafer taken from the second cleaning module 502 into the drying module 6. Afterwards, the Z-axis moving module moves above the anterior cleaning channel module 4. Above operations are repeated.

### Embodiment 3

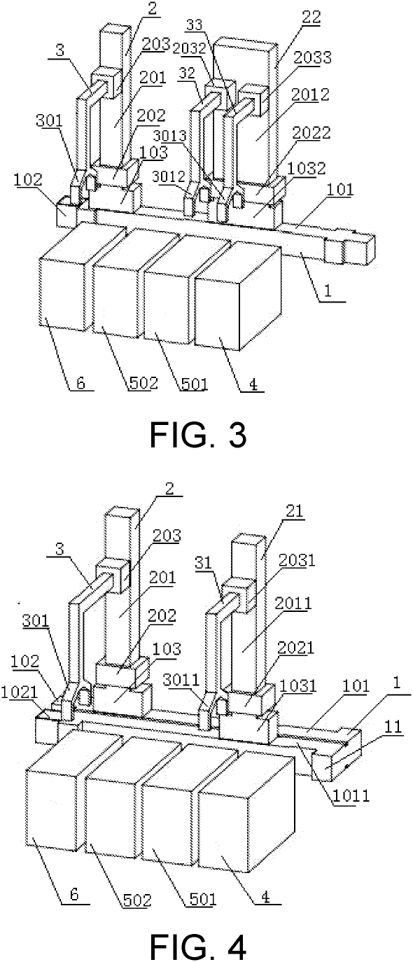

As shown in FIG. 3, it is the third embodiment of the cleaning module of the CMP machine provided in the present disclosure, compared with the first embodiment, the third embodiment further includes one second Z-axis moving module 22 and one second claw clamping arm module 32 and one third claw clamping arm module 33. The wafer transfer device of the cleaning module of the CMP machine provided in this embodiment includes the X-axis moving module 1, the Z-axis moving module 2, the second Z-axis moving module 22, the claw clamping arm module 3 and the second claw clamping arm module 32 and the third claw clamping arm module 33. The X-axis moving module 1 is deposited on a side of the cleaning module of the CMP machine, the X-axis moving module 1 includes a X-transfer axis 101, an X-axis driver 102, an X-axis moving slider 103 and a second X-axis moving slider 1032, the X-axis moving slider 103 and the second X-axis moving slider 1032 independently move on the X-transfer axis 101. The Z-axis moving module 2 is fixedly installed on the X-axis moving slider 103, the Z-axis moving module 2 includes a Z-transfer axis 201, a Z-axis driver 202 and a Z-axis moving slider 203. The second Z-axis moving module 22 is fixedly installed on the second X-axis moving slider 1032, the second Z-axis moving module 22 includes a second Z-transfer axis 2012, a second Z-axis driver 2022, a second Z-axis moving slider 2032 and a third Z-axis moving slider 2033. The Z-axis moving module 2 and the second Z-axis moving module 22 independently move on the X-axis moving module 1. The claw clamping arm module 3 is installed on the Z-axis moving slider 203, the claw clamping arm module 3 includes a claw clamping arm 301, which can rotate around the Z-axis moving slider 203. The second claw clamping arm module 32 is installed on the second Z-axis moving slider 2032, the second claw clamping arm module 32 includes a second claw clamping arm 3012, which can rotate around the second Z-axis moving slider 2032. The third claw clamping arm module 33 is installed on the third Z-axis moving slider 2033, the third claw clamping arm module 33 includes a third claw clamping arm 3013, which can rotate around the third Z-axis moving slider 2033.

In this embodiment, the wafer transfer method of the wafer transfer device of the cleaning module of the CMP machine is:

The X-axis driver 102 moves and drives the second Z-axis moving module 22 to move above the anterior cleaning channel module 4, the third claw clamping arm 3013 takes out one wafer o be cleaned from the anterior cleaning channel module 4. Then, the second Z-axis moving module 22 further moves above the first cleaning module 501, the second claw clamping arm 3012 takes out the wafer from the first cleaning module 501, the third claw clamping arm 3013 places the wafer taken from the anterior cleaning channel module 4 into the first cleaning module 501. The Z-axis moving module 2 moves above the second cleaning module 502, the claw clamping arm 301 takes out the wafer from the second cleaning module 502. The Z-axis moving module 2 further moves above the drying module 6, the claw clamping arm 301 places the wafer taken from the second cleaning module 502 into the drying module 6. The second Z-axis moving module 22 further moves above the second cleaning module 502, the second claw clamping arm 3012 places the wafer taken from the first cleaning module 501 into the second cleaning module 502. Afterwards, the second Z-axis moving module 22 further moves above the anterior cleaning channel module 4. Above operations are repeated.

### Embodiment 4

As shown in FIG. 4, it is the fourth embodiment of the cleaning module of the CMP machine provided in the present disclosure, compared with the first embodiment, the fourth embodiment further includes one first X-axis moving module 11, one first Z-axis moving module 21 and one first claw clamping arm module 31. The wafer transfer device of the cleaning module of the CMP machine provided in this embodiment includes the X-axis moving module 1, the first X-axis moving module 11, the Z-axis moving module 2, the first Z-axis moving module 21, the claw clamping arm module 3 and the first claw clamping arm module 31. The X-axis moving module 1 and the first X-axis moving module 11 are overlapping installed along a Y-axis and are deposited on a side of the cleaning module of the CMP machine. The X-axis moving module 1 includes a X-transfer axis 101, an X-axis driver 102 and an X-axis moving slider 103. The first X-axis moving module 11 includes a first X-transfer axis 1011, a first X-axis driver 1021 and a first X-axis moving slider 1031. The Z-axis moving module 2 is fixedly installed on the X-axis moving slider 103, the Z-axis moving module 2 includes a Z-transfer axis 201, a Z-axis driver 202 and a Z-axis moving slider 203. The first Z-axis moving module 21 is fixedly installed on the first X-axis moving slider 1031, the first Z-axis moving module 21 includes a first Z-transfer axis 2011, a first Z-axis driver 2021 and a first Z-axis moving slider 2031. The claw clamping arm module 3 is installed on the Z-axis moving slider 203, the claw clamping arm module 3 includes a claw clamping arm 301, which can rotate around the Z-axis moving slider 203. The first claw clamping arm module 31 is installed on the first Z-axis moving slider 2031, the first claw clamping arm module 31 includes a first claw clamping arm 3011, which can rotate around the first Z-axis moving slider 2031.

In this embodiment, the wafer transfer method of the wafer transfer device of the cleaning module of the CMP machine is:

The X-axis driver 102 drives the Z-axis moving module 2 to move above the anterior cleaning channel module 4, the claw clamping arm 301 takes out one wafer to be cleaned from the anterior cleaning channel module 4. The first X-axis driver 1021 drives the first Z-axis moving module 21 to move above the first cleaning module 501, the first claw clamping arm 3011 takes out the wafer from the first cleaning module 501. Then, the Z-axis moving module 2 moves above the first cleaning module 501, the claw clamping arm 301 places the wafer taken from the anterior cleaning channel module 4 into the first cleaning module 501. The Z-axis moving module 2 further moves above the second cleaning module 502, the claw clamping arm 301 takes out the wafer from the second cleaning module 502. The first Z-axis moving module 21 further moves above the second cleaning module 502, the first claw clamping arm 3011 places the wafer taken from the first cleaning module 501 into the second cleaning module 502. The Z-axis moving module 2 further moves above the drying module 6, the claw clamping arm 301 places the wafer taken from the second cleaning module 502 into the drying module 6. Afterwards, the Z-axis moving module 2 moves above the anterior cleaning channel module 4. Above operations are repeated.

### Embodiment 5

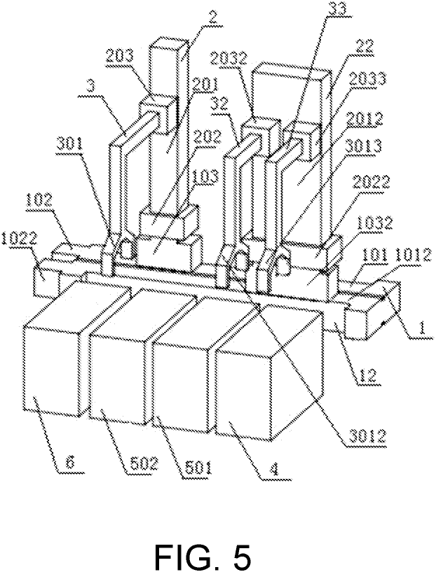

As shown in FIG. 5, it is the fifth embodiment of the cleaning module of the CMP machine provided in the present disclosure, compared with the first embodiment, the fifth embodiment further includes one second X-axis moving module 12, one second Z-axis moving module 22, one second claw clamping arm module 32 and one third claw clamping arm module 33. The wafer transfer device of the cleaning module of the CMP machine provided in this embodiment includes the X-axis moving module 1, the second X-axis moving module 12, the Z-axis moving module 2, the second Z-axis moving module 22, the claw clamping arm module 3, the second claw clamping arm module 32 and the third claw clamping arm module 33. The X-axis moving module 1 and the second X-axis moving module 12 are overlapping installed along the Y-axis and are deposited on a side of the cleaning module of the CMP machine. The X-axis moving module 1 includes a X-transfer axis 101, an X-axis driver 102 and an X-axis moving slider 103. The second X-axis moving module 12 includes a second X-transfer axis 1012, a second X-axis driver 1022 and a second X-axis moving slider 1032. The Z-axis moving module 2 is fixedly installed on the X-axis moving slider 103, the Z-axis moving module 2 includes a Z-transfer axis 201, a Z-axis driver 202 and a Z-axis moving slider 203. The second Z-axis moving module 22 is fixedly installed on the second X-axis moving slider 1032, the second Z-axis moving module 22 includes a second Z-transfer axis 2012, a second Z-axis driver 2022, a second Z-axis moving slider 2032 and a third Z-axis moving slider 2033. The claw clamping arm module 3 is installed on the Z-axis moving slider 203, the claw clamping arm module 3 includes a claw clamping arm 301, which can rotate around the Z-axis moving slider 203. The second claw clamping arm module 32 is installed on the second Z-axis moving slider 2032, the second claw clamping arm module 32 includes a second claw clamping arm 3012, which can rotate around the second Z-axis moving slider 2032. The third claw clamping arm module 33 is installed on the third Z-axis moving slider 2033, the third claw clamping arm module 33 includes a third claw clamping arm 3013, which can rotate around the third Z-axis moving slider 2033.

In this embodiment, the wafer transfer method of the wafer transfer device of the cleaning module of the CMP machine is:

The second X-axis driver 1022 drives the second Z-axis moving module 22 to move above the anterior cleaning channel module 4, the third claw clamping arm 3013 takes out one wafer to be cleaned from the anterior cleaning channel module 4. The second Z-axis moving module 22 further moves above the first cleaning module 501, the second claw clamping arm 3012 takes out the wafer from the first cleaning module 501, the third claw clamping arm 3013 places the wafer taken from the anterior cleaning channel module 4 into the first cleaning module 501. The X-axis driver 102 drives the Z-axis moving module 2 to move above the second cleaning module 502, the claw clamping arm 301 takes out the wafer from the second cleaning module 502. The Z-axis moving module 2 further moves above the drying module 6, the claw clamping arm 301 places the wafer taken from the second cleaning module 502 into the drying module 6. Then, the second Z-axis moving module 22 further moves above the second cleaning module 502, the second claw clamping arm 3012 places the wafer taken from the first cleaning module 501 into the second cleaning module 502. Afterwards, the second Z-axis moving module 22 further moves above the anterior cleaning channel module 4. Above operations are repeated.

### Embodiment 6

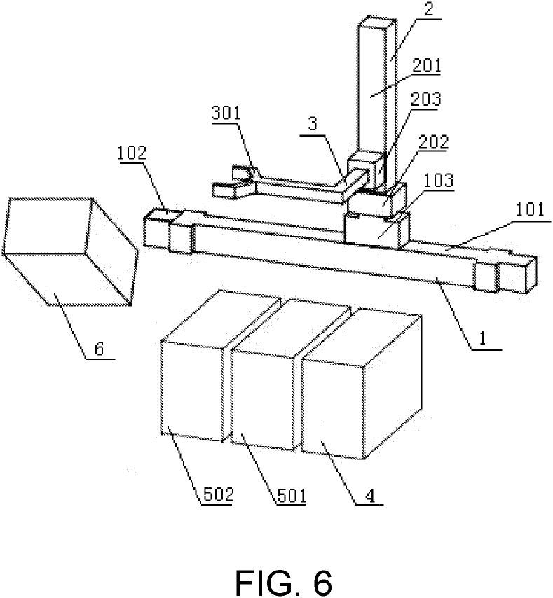

Cleaning modules of the cleaning module of the CMP machine provided in above embodiments are all vertically placed wafer. When one module of the cleaning modules is horizontally placed the wafer, the claw clamping arm module provided in this embodiment can rotate around the Z-axis moving slider to perform the switch of vertical placement and horizontal placement of the wafer. As shown in FIG. 6, it is the sixth embodiment provided in the present disclosure, in this embodiment, the anterior cleaning channel module 4, the first cleaning module 501 and the second cleaning module 502 are vertically placed the wafer, and the drying module 6 is horizontally placed the wafer. The wafer transfer device of the cleaning module of the CMP machine provided in this embodiment includes the X-axis moving module 1, the Z-axis moving module 2 and the claw clamping arm module 3. The X-axis moving module is deposited on a side of the cleaning module of the CMP machine, the X-axis moving module 1 includes a X-transfer axis 101, an X-axis driver 102 and an X-axis moving slider 103. The Z-axis moving module 2 is fixedly installed on the X-axis moving slider 103, the Z-axis moving module 2 includes a Z-transfer axis 201, a Z-axis driver 202 and a Z-axis moving slider 203. The claw clamping arm module 3 is installed on the Z-axis moving slider 203, the claw clamping arm module 3 includes a claw clamping arm 301, which can rotate around the Z-axis moving slider 203.

In this embodiment, the wafer transfer method of the wafer transfer device of the cleaning module of the CMP machine is:

The X-axis driver 102 drives the Z-axis moving module 2 to move to a side of the drying module 6, the claw clamping arm 301 rotates 90° around the Z-axis moving slider 203, the claw clamping arm 301 takes out the completely dried wafer from the drying module 6 and places the wafer into the following process of the CMP machine. Then, the claw clamping arm 301 rotates -90° around the Z-axis moving slider 203, the Z-axis moving module 2 moves above the second cleaning module 502, the claw clamping arm 301 takes out the wafer from the second cleaning module 502. The Z-axis moving module 2 further moves to the side of the drying module 6, the claw clamping arm 301 rotates 90° around the Z-axis moving slider 203, the claw clamping arm 301 places the wafer taken from the second cleaning module 502 into the drying module 6. After that, the claw clamping arm 301 rotates -90° around the Z-axis moving slider 203, the Z-axis moving module 2 moves above the first cleaning module 501, the claw clamping arm 301 takes out the wafer from the first cleaning module 501. The Z-axis moving module 2 further moves above the second cleaning module 502, the claw clamping arm 301 places the wafer taken from the first cleaning module 501 into the second cleaning module 502. The Z-axis moving module 2 further moves above the anterior cleaning channel module 4, the claw clamping arm 301 takes out one wafer to be cleaned from the anterior cleaning channel module 4. The Z-axis moving module 2 further moves above the first cleaning module 501, the claw clamping arm 301 places the wafer taken from the anterior cleaning channel module 4 into the first cleaning module 501. Afterwards, the Z-axis moving module 2 moves to the side of the drying module 6. Above operations are repeated.

The present disclosure has following advantages:

In the present disclosure, the X-axis moving module of the wafer transfer device is installed at the lower end of the Z-axis moving module, it reduces the possibility that impurities and particles generated during the use of the wafer transfer device falling into the cleaning module of the CMP machine, and improves the wafer cleaning effect. Meanwhile, the X-axis moving module is installed at the lower end of the Z-axis moving module, it greatly lowers the overall center of gravity of the wafer transfer device, moves the claw clamping arm at a height closer to the cleaning module of the CMP machine, reduces the tremble of the claw clamping arm in the process of picking up and placing the wafer, and enhances the stability of the claw clamping arm module. Moreover, it increases the number of the X-axis moving module and Z-axis moving module, can flexibly configurate the wafer transfer method, and shortens the overall wafer transfer time.

Although the content of the present disclosure is introduced in detail through the above preferred embodiments, it should note that the above description shall not be considered as any limitation on the present disclosure. By reading the above description, those skilled in the art can develop obvious modifications and substitutions of the present disclosure. Therefore, the scope for which protection is sought of the present disclosure should be defined by the attached claims.

1. A wafer transfer device for a cleaning module of a chemical mechanical planarization machine, the cleaning module of the chemical mechanical planarization machine comprising an anterior cleaning channel module, a cleaning module and a drying module, the wafer transfer device comprising:
a claw clamping arm module for picking up and placing a wafer;
a Z-axis moving module, connected to the claw clamping arm module for performing a movement of the claw clamping arm module in a Z-axis direction;
an X-axis moving module, connected to a lower end of the Z-axis moving module for performing a movement of the claw clamping arm module in a X-axis direction.

2. The wafer transfer device according to claim 1, wherein the X-axis moving module comprises:
a X-transfer axis;
an X-axis driver; and
an X-axis moving slider,
wherein the X-axis driver drives the X-axis moving slider installed on the X-transfer axis to move in the X-axis direction along the X-transfer axis, and the X-axis moving slider is connected to the Z-axis moving module.

3. The wafer transfer device according to claim 2, wherein the Z-axis moving module comprises:
a Z-transfer axis;
a Z-axis driver; and
a Z-axis moving slider,
wherein the Z-axis driver drives the Z-axis moving slider installed on the Z-transfer axis to move in the Z-axis direction along the Z-transfer axis, and the Z-axis moving slider is connected to the claw clamping arm module.

4. The wafer transfer device according to claim 3, wherein the claw clamping arm module comprises a claw clamping arm, wherein the claw clamping arm takes the Z-axis moving slider as an original point and rotates 360° on a plane formed by an X-axis and a Z-axis.

5. A cleaning module of a chemical mechanical planarization machine, comprising:
an anterior cleaning channel module;
a cleaning module;
a drying module; and
the wafer transfer device according to claim 1.

6. A wafer transfer method of the wafer transfer device according to claim 1, comprising:
a step that the X-axis moving module drives the Z-axis moving module and the claw clamping arm module to move in the X-axis direction to perform a movement of the wafer between any two of the anterior cleaning channel module, the cleaning module and the drying module;
a step that the Z-axis moving module drives the claw clamping arm module to move in the Z-axis direction to perform a movement of the wafer at any one of the anterior cleaning channel module, the cleaning module and the drying module in the Z-axis direction; and
a step that the claw clamping arm module performs picking up and placing the wafer at any one of the anterior cleaning channel module, the cleaning module and the drying module.

7. The wafer transfer method according to claim 6, wherein the X-axis driver drives the X-axis moving slider installed on the X-transfer axis to move in the X-axis direction along the X-transfer axis, and the X-axis moving slider drives the Z-axis moving slider to move in the X-axis direction along the X-transfer axis.

8. The wafer transfer method according to claim 7, wherein the Z-axis driver drives the Z-axis moving slider installed on the Z-transfer axis to move in the Z-axis direction along the Z-transfer axis, and the Z-axis moving slider drives the claw clamping arm module to move in the Z-axis direction along the Z-transfer axis.

9. The wafer transfer method according to claim 8, wherein the claw clamping arm takes the Z-axis moving slider as the original point and rotates 360° on the plane formed by the X-axis and the Z-axis.

10. A cleaning module of a chemical mechanical planarization machine, comprising:
an anterior cleaning channel module;
a cleaning module;
a drying module; and
the wafer transfer device according to claim 2.

11. A cleaning module of a chemical mechanical planarization machine, comprising:
an anterior cleaning channel module;
a cleaning module;
a drying module; and
the wafer transfer device according to claim 3.

12. A cleaning module of a chemical mechanical planarization machine, comprising:
an anterior cleaning channel module;
a cleaning module;
a drying module; and
the wafer transfer device according to claim 4.

13. A wafer transfer method of the wafer transfer device according to claim 2, comprising:
a step that the X-axis moving module drives the Z-axis moving module and the claw clamping arm module to move in the X-axis direction to perform a movement of the wafer between any two of the anterior cleaning channel module, the cleaning module and the drying module;
a step that the Z-axis moving module drives the claw clamping arm module to move in the Z-axis direction to perform a movement of the wafer at any one of the anterior cleaning channel module, the cleaning module and the drying module in the Z-axis direction; and
a step that the claw clamping arm module performs picking up and placing the wafer at any one of the anterior cleaning channel module, the cleaning module and the drying module.

14. A wafer transfer method of the wafer transfer device according to claim 3, comprising:
a step that the X-axis moving module drives the Z-axis moving module and the claw clamping arm module to move in the X-axis direction to perform a movement of the wafer between any two of the anterior cleaning channel module, the cleaning module and the drying module;
a step that the Z-axis moving module drives the claw clamping arm module to move in the Z-axis direction to perform a movement of the wafer at any one of the anterior cleaning channel module, the cleaning module and the drying module in the Z-axis direction; and
a step that the claw clamping arm module performs picking up and placing the wafer at any one of the anterior cleaning channel module, the cleaning module and the drying module.

15. A wafer transfer method of the wafer transfer device according to claim 4, comprising:
a step that the X-axis moving module drives the Z-axis moving module and the claw clamping arm module to move in the X-axis direction to perform a movement of the wafer between any two of the anterior cleaning channel module, the cleaning module and the drying module;
a step that the Z-axis moving module drives the claw clamping arm module to move in the Z-axis direction to perform a movement of the wafer at any one of the anterior cleaning channel module, the cleaning module and the drying module in the Z-axis direction; and
a step that the claw clamping arm module performs picking up and placing the wafer at any one of the anterior cleaning channel module, the cleaning module and the drying module.
